(19) United States
(12) Patent Application Publication
(10) Pub. No.: US 2025/0105796 A1
(43) Pub. Date: Mar. 27, 2025

(54) GATE VOLTAGE LEVEL SHIFTING CIRCUIT

(71) Applicant: MACOM Technology Solutions Holdings, Inc., Lowell, MA (US)

(72) Inventor: Benone Achiriloaie, Riverside, CA (US)

(21) Appl. No.: 18/897,995

(22) Filed: Sep. 26, 2024

Related U.S. Application Data
(60) Provisional application No. 63/585,384, filed on Sep. 26, 2023.

(51) Int. Cl. H03F 1/30; H03F 3/21; H03K 19/0185

(52) U.S. Cl. CPC H03F 1/301; H03F 3/21; H03K 19/018521; H03F 2200/451

(57) ABSTRACT

Aspects of gate voltage level shifting circuits are described. An example power amplifier includes a depletion mode power transistor and a level shift circuit. The level shift circuit is configured to generate a level-shifted gate bias control signal for the depletion mode power transistor based on a gate bias control signal. Among other benefits, the level shift circuit facilitates the replacement of the power transistor in a power amplifier system, particularly in cases where the gate bias control levels generated by the amplifier system are insufficient to completely pinch-off the depletion mode power transistor.

### CROSS-REFERENCE TO RELATED APPLICATIONS

This application claims the benefit of and priority to U.S. Provisional Application No. 63/585,384, filed Sep. 26, 2023, titled “GATE VOLTAGE LEVEL SHIFTING CIRCUIT,” the entire contents of which is hereby incorporated herein by reference.

### BACKGROUND

An amplifier is an electronic circuit or device designed to increase the power level of an input signal. Amplifiers can be defined according to the properties of their outputs to their inputs, among other characteristics. As one example, gain can be defined as the ratio between the magnitudes of the output and input signals of an amplifier. Gain can be unitless and expressed in decibels. Amplifiers are typically designed to have linear gain over a certain operating frequency range or bandwidth, although amplifiers can also be designed to achieve a range of different performance characteristics depending upon the application.

Semiconductor transistors are commonly used as amplifiers. Transistors formed from gallium nitride (GaN) materials are capable of amplifying radio frequency (RF) signals at high power. Depletion mode gallium nitride (GaN) transistors, for example, are often relied upon as high-power amplifiers for RF signals. Depletion mode transistors are normally “on” at zero gate-source voltage. If a voltage is applied between the drain and the source of such a transistor when the gate-source voltage is zero, a large, potentially destructive current may flow through the device.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example power amplifier includes a printed circuit board (PCB) with a control input and a power input, a depletion mode power transistor on the PCB, and a level shift circuit configured to generate a level-shifted gate bias control signal for the depletion mode power transistor based on a gate bias control signal received at the control input. An example power amplifier includes a depletion mode power transistor and a level shift circuit. The level shift circuit is configured to generate a level-shifted gate bias control signal for the depletion mode power transistor based on a gate bias control signal.

The level shift circuit can include a voltage generator, a voltage reference generator, and a level shifter in one example. The voltage generator can include a linear regulator and a charge pump, and the voltage reference generator can include a resistor voltage divider in one implementation. The voltage generator is configured to generate a shifted voltage based on a supply voltage provided at the power input, and the voltage reference generator is configured to provide a reference voltage based on the shifted voltage.

In one aspect of the embodiments, the level shift circuit is configured to shift a first voltage level of the gate bias control signal to a second voltage level for the level-shifted gate bias control signal, based on a comparison of the gate bias control signal to a reference voltage. In another aspect, the level shift circuit is configured to expand first voltage levels of the gate bias control signal to second voltage levels for the level-shifted gate bias control signal. In still another aspect, the level shift circuit is configured to expand first voltage levels of the gate bias control signal to second voltage levels for the level-shifted gate bias control signal, based on the gate bias control signal received at the control input and whether a supply voltage is provided at the power input.

An example level shift circuit for gate bias control includes a voltage generator configured to generate a reference voltage based on a supply voltage, and a level shifter configured to receive a gate bias control signal for a power transistor and to generate a level-shifted gate bias control signal for the power transistor based on the reference voltage. The voltage generator can include a linear regulator and a charge pump in one implementation. The voltage generator can be configured to generate a shifted voltage based on the supply voltage, and a voltage reference generator can be configured to generate the reference voltage based on the shifted voltage.

Another example level shift circuit for gate bias control includes a voltage generator configured to generate a shifted voltage based on a supply voltage, a voltage reference generator configured to generate a reference voltage based on the shift voltage, and a level shifter configured to receive a gate bias control signal and to generate a level-shifted gate bias control signal. The voltage generator can include a linear regulator and a charge pump in one implementation. The voltage generator can be configured to generate a shifted voltage based on the supply voltage, and a voltage reference generator can be configured to generate the reference voltage based on the shifted voltage.

In other aspects of the embodiments, the level shifter is configured to shift a first voltage level of the gate bias control signal to a second voltage level for the level-shifted gate bias control signal, based on a comparison of the gate bias control signal to the reference voltage. In another aspect, the level shift circuit is configured to expand first voltage levels of the gate bias control signal to second voltage levels for the level-shifted gate bias control signal. In still other aspects, when the supply voltage is provided, the level shift circuit is configured to expand first voltage levels of the gate bias control signal to second voltage levels for the level-shifted gate bias control signal based on a comparison of the gate bias control signal to the reference voltage. When the supply voltage is not provided, the level shift circuit is configured to pass gate bias control signal as the level-shifted gate bias control signal.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an amplifier system according to various aspects of the embodiments described herein.

FIG. 2 illustrates an amplifier with a level shift circuit according to various aspects of the embodiments described herein.

FIG. 3 illustrates the amplifier and a detailed view of the level shift circuit shown in FIG. 2 according to various aspects of the embodiments described herein.

FIG. 4 illustrates a detailed view of the level shift circuit shown in FIG. 3 according to various aspects of the embodiments described herein.

FIG. 5 illustrates example waveforms for a gate bias control signal and a level-shifted gate bias control signal over time according to various aspects of the embodiments described herein.

### DETAILED DESCRIPTION

Semiconductor transistors are commonly used as amplifiers. A transistor can be configured as a certain type or class of amplifier based on which terminal of the transistor is common to both the input and the output circuit. For bipolar junction transistors, the amplifier classes include common emitter, common base, and common collector. For field-effect transistors (FETs), the amplifier classes include common source, common gate, and common drain. Several transistors can be coupled together to form larger and more complex amplifier circuits including one or more amplifier stages. Examples of such amplifier circuits include differential amplifiers, distributed amplifiers, and amplifiers including dedicated preamplifier, low-noise, output, and other stages.

Among other design considerations, transistor biasing is an important factor in the design of an amplifier. Transistor biasing is related to the selection of the DC voltages that are applied at the drain, source, and gate of a FET transistor during operation. Transistors formed from gallium nitride (GaN) materials are capable of radio frequency (RF) power amplification at high power. Depletion mode GaN transistors are often relied upon as high-power amplifiers for radio frequency (RF) signals. Depletion mode transistors are normally “on” at zero gate-source voltage. If a relatively large voltage for power is applied across the drain and source terminals of such a transistor when the gate bias voltage is zero or greater, a large and potentially destructive current may flow through the transistor. Thus, a negative bias voltage is typically applied to the gate of a depletion mode GaN transistor, to pinch off the channel of the transistor, before power is supplied across the drain and source terminals of the transistor. The negative gate bias voltage helps to limit or eliminate the flow of current through the channel of the transistor when the drain-to-source voltage is applied. Thus, biasing and sequencing circuitry is often relied upon to control the sequence of voltage biasing and power applied to depletion mode GaN and related transistors.

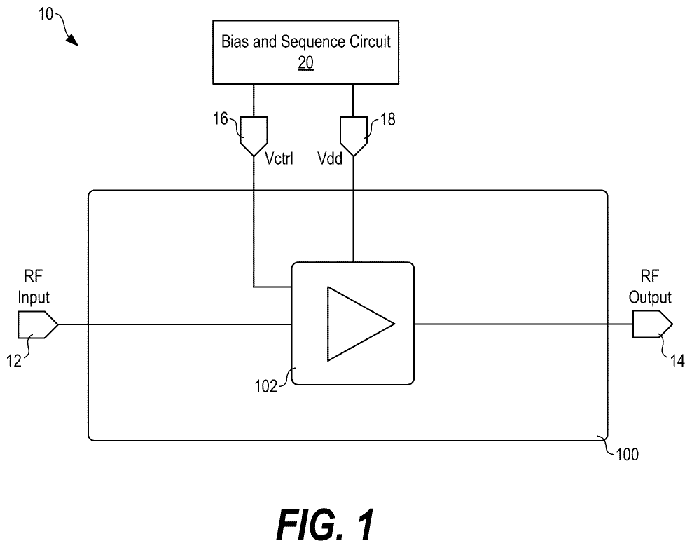

In the context outlined above, aspects of gate voltage level shifting circuits are described. An example amplifier system includes a power amplifier on a printed circuit board (PCB), with a gate bias control input, a power input, a depletion mode power transistor, and a level shift circuit on the PCB. The level shift circuit is configured to generate a level-shifted gate bias control signal for the depletion mode power transistor based on a gate bias control signal received at the gate bias control input. Among other benefits, the level shift circuit facilitates the replacement of the power transistor in the amplifier system, particularly in cases where the gate bias control levels generated by the amplifier system are insufficient to completely pinch-off the depletion mode power transistor. Turning to the drawings, FIG. 1 illustrates an amplifier system 10 (“system 10”). Among other components, the system 10 includes bias and sequence circuit 20 and a pallet amplifier 100. The system 10 is depicted as a representative example in FIG. 1. In practice, the system 10 can include other components that are not shown or illustrated. The system can also omit components in some cases, including components described below and components illustrated in FIG. 1.

The pallet amplifier 100 can be embodied as a printed circuit board (PCB) including one or more semiconductor transistors amplifiers for RF signal amplification. The pallet amplifier 100 can include input matching networks, power transistors, output matching networks, power and bias inputs, RF input connectors, RF output connectors, and other components. The gate control level shifting circuitry described herein can be applied to the pallet amplifier 100 in the system 10, as one example, although the level shifting concepts are not limited to use with any particular type, style, or arrangement of transistor amplifiers, pallet amplifiers, or amplifier systems.

The pallet amplifier 100 includes an amplifier 102, an input 12, an output 14, a bias control input 16, and a power input 18 among other components. A gate bias control signal “Vctrl” (also “Vctrl signal”) is provided to the bias control input 16 of the pallet amplifier 100 from the bias and sequence circuit 20. A supply voltage “Vdd” (also “Vdd supply voltage”) is supplied or otherwise provided to the power input 18 of the pallet amplifier 100 by the bias and sequence circuit 20. The Vctrl signal provides a gate bias potential or voltage for the gate terminal or terminals of one or more FETs of the amplifier 102, as described below. An RF signal for amplification can also be applied to the gate terminals of the amplifier 102, as would be understood in the field. The Vdd supply voltage provides power for the amplifier 102, as also described below.

The amplifier 102 can be embodied as one or more semiconductor transistors. As examples, the amplifier 102 can be embodied as one or more depletion mode high electron mobility transistors (HEMTs) formed in GaN or GaN materials, although the amplifier 102 can be embodied as other types of transistors. The amplifier 102 can be embodied as a single stage or multi-stage transistor amplifier. As one example, the amplifier 102 can include a two-stage cascode arrangement of transistors, including a first common source transistor stage that feeds a second common gate transistor stage. The amplifier 102 can also be embodied as other multi-stage arrangements of transistor amplifiers. The amplifier 102 can be capable of linear, saturated, pulsed, and other operating modes. The amplifier 102 can also operate at hundreds or thousands of Watts of power, based on power supplied at potentials of tens or even hundreds of Volts.

The pallet amplifier 100 receives the Vctrl signal at the bias control input 16. The Vctrl signal can be relied upon as a gate bias control voltage for the amplifier 102. The pallet amplifier 100 also receives the Vdd supply voltage at the power input 18. The Vdd supply voltage provides power for the amplifier 102. More particularly, the Vctrl signal can be applied to the gate terminal of a depletion mode power transistor in the amplifier 102 as a gate bias control voltage. The Vdd supply voltage can be applied to the drain of the power transistor in the amplifier 102 as a supply of power. The Vctrl signal and the Vdd supply voltage can also be applied in a similar way among two or more power transistors in the amplifier 102, if the amplifier 102 is embodied as a multi-stage arrangement of transistor amplifiers.

The application of the Vctrl signal and the Vdd supply voltage to the amplifier 102 can be timed and sequenced by the bias and sequence circuit 20, to protect the depletion mode power transistor or transistors in the amplifier 102. Depletion mode power transistors formed from GaN and other types of semiconductor materials can rely upon a sequenced application of gate and drain voltage potentials to avoid failure modes. For example, a large and potentially destructive current can flow through a depletion mode transistor if a drain-to-source voltage is applied across it when a voltage of zero (or greater) is applied at the gate of the transistor. Thus, in operation, the bias and sequence circuit 20 is configured to set the Vctrl signal to a negative potential for gate biasing in the amplifier 102 before it supplies or provides the Vdd supply voltage to the amplifier 102. As an example, the bias and sequence circuit 20 can first provide a Vctrl signal voltage of −5V before providing or supplying a Vdd supply voltage of 80V. The bias and sequence circuit 20 can provide the Vctrl signal and Vdd supply at other potentials, however.

In some cases, the bias and sequence circuit 20 can be particularly designed for use with the amplifier 102. For example, the bias and sequence circuit 20 can be designed to provide the Vctrl signal at levels of −5V to turn the amplifier 102 off (i.e., to pinch off the channel of the amplifier 102) and −2.2V to turn the amplifier 102 on. The “on” and “off”′ voltage levels for Vctrl can be selected based on the characteristics of the transistors in the amplifier 102. The gate biasing needed to turn the amplifier 102 fully on and fully off depends upon the type, arrangement, size, and other attributes of the transistor or transistors in the amplifier 102. Thus, if the pallet amplifier 100 were exchanged in the system 10 with a replacement amplifier, then the on and off levels of the Vctrl signal provided by the bias and sequence circuit 20 may not be suitable to control the replacement amplifier. More particularly, an off potential of −5V from the bias and sequence circuit 20 may be insufficient to fully turn or pinch off the channel of the replacement amplifier.

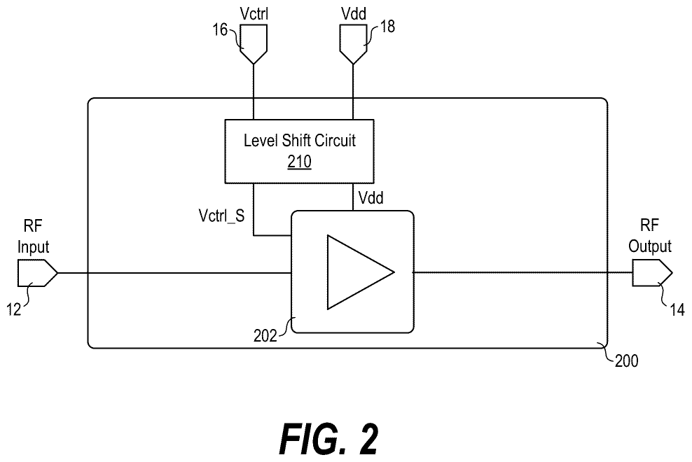

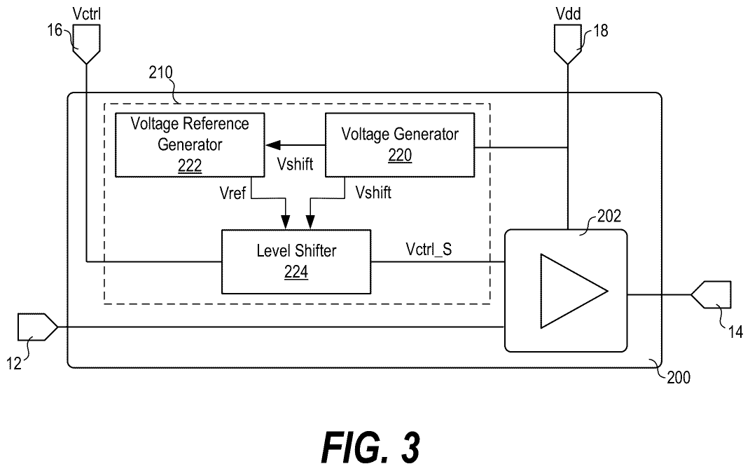

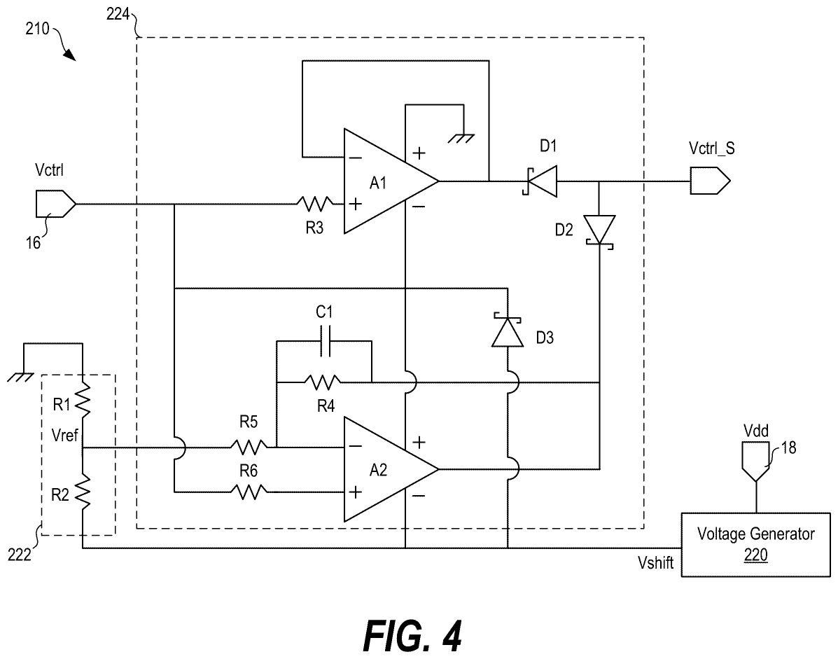

FIG. 2 illustrates a pallet amplifier 200 with a level shift circuit 210. The pallet amplifier 200 includes an amplifier 202, the level shift circuit 210, an input 12, an output 14, a bias control input 16, and a power input 18. The pallet amplifier 200 is depicted as a representative example in FIG. 2. In practice, the pallet amplifier 200 can include other components that are not shown or illustrated. The pallet amplifier 200 can also omit certain components in some cases, including one or more of the components described below and illustrated in FIGS. 3 and 4.

The pallet amplifier 200 can be embodied as a PCB including one or more semiconductor transistors amplifiers for RF signal amplification. The pallet amplifier 200 can include input matching networks, power transistors, output matching networks, power and bias inputs, RF input connectors, RF output connectors, and other components. The level shift circuit 210 can be implemented as a component of the pallet amplifier 200, as one example, although the level shifting concepts are not limited to use with any particular type, style, or arrangement of transistor amplifiers, pallet amplifiers, or amplifier systems.

The gate control voltage signal Vctrl is provided to the bias control input 16 of the pallet amplifier 200. The supply voltage Vdd is supplied or otherwise provided to the power input 18 of the pallet amplifier 200. The Vctrl signal provides a gate bias potential for the amplifier 202, and the Vdd supply voltage provides power for the amplifier 202. The Vctrl signal and the Vdd supply voltage can be provided from the bias and sequence circuit 20 shown in FIG. 1, for example, or from related biasing and sequencing circuitry.

The levels of the Vctrl signal provided to the bias control input 16 may not be sufficient for the operation of the amplifier 202 in some circumstances. For example, as compared to the amplifier 102 described above, the amplifier 202 may depend upon a different gate bias voltage to turn fully off (i.e., to completely pinch-off the amplifier 202). A gate bias voltage of −5V may be sufficient to fully turn off the amplifier 102, but a gate bias voltage of −7V or greater may be needed to fully turn off the amplifier 202. In this case, a Vctrl signal level of −5V may be an insufficient bias voltage to completely stop the flow of current through the amplifier 202. This can result in lost efficiency, excess heat dissipation, and other issues in the operation of the amplifier 202.

The pallet amplifier 200 includes the level shift circuit 210 to address the issues outlined above. The level shift circuit 210 is configured to shift one or more voltage levels of the Vctrl signal, as they are provided at the bias control input 16, to one or more different voltage levels for operation of the amplifier 202. As one example, the level shift circuit 210 can be configured to expand the voltage range or levels of the Vctrl signal from between about −2V and −5V to between −2V and −8V, and other voltages are within the scope of the examples. The level shift circuit 210 and the concepts of gate bias control signal level shifting, as described herein, are not limited to level shifting of certain voltages or voltage ranges. Rather, the level shift circuit 210 can be designed to shift voltage levels of the Vctrl signal to a range of different voltage levels depending on the design of the amplifier 202 and the needs of the design.

As shown in FIG. 2, the level shift circuit 210 receives the Vctrl signal and the Vdd supply voltage as inputs. The level shift circuit 210 is configured to regulate and convert the Vdd supply voltage to a potential (or potentials) needed for level shifting the Vctrl signal. The level shift circuit 210 includes a voltage generator for converting the Vdd supply voltage to a shifted voltage Vshift. The level shift circuit 210 also includes a voltage reference generator, and the voltage reference generator generates a reference voltage Vref using the shifted voltage Vshift. The level shift circuit 210 also includes a level shifter. The level shifter is configured to generate a level-shifted version of the Vctrl signal, which is identified in FIG. 2 as the level-shifted Vctrl_S signal, based on a comparison of the Vctrl signal with the reference voltage Vref. The Vctrl_S signal is provided to the amplifier 202 as a gate bias. The potentials (e.g., “on” and “off” potentials) of the Vctrl_S signal can be different than those of the Vctrl signal. For example, the potentials of the Vctrl_S signal can be larger or more expansive than those of the Vctrl signal. These and other aspects of the embodiments are described below.

FIG. 3 illustrates the amplifier 200 and a more detailed view of the level shift circuit 210 shown in FIG. 2. The level shift circuit 210 includes a voltage generator 220, a voltage reference generator 222, and a level shifter 224. The components of the level shift circuit 210 are illustrated as a representative example in FIG. 3. The level shift circuit 210 can also be structured and configured in other ways as compared to that shown and described.

The voltage generator 220 is configured to convert a first voltage to a second, and different, voltage. In the examples described herein, the voltage generator 220 is configured to convert the Vdd supply voltage a shifted voltage Vshift. The voltage generator 220 can convert a relatively larger Vdd supply voltage to a relatively lower Vshift voltage, which is used for level shifting the Vctrl signal. The voltage generator 220 can convert a positive Vdd supply voltage to a negative Vshift voltage. As examples, the voltage generator 220 can convert Vdd supply voltages of 50V, 60V, 70V, 80V, 90V, or larger voltages to negative Vshift voltages of −5V, −8V, −10V, −12V, −15V, or lower voltages.

The Vshift voltage is provided by the voltage generator 220 to the voltage reference generator 222. The Vshift voltage is also provided by the voltage generator 220 to the level shifter 224. The voltage generator 220 can be embodied as an active linear regulator followed by a charge pump, as one example, but the voltage generator 220 can be embodied as other types of voltage regulators. The linear regulator of the voltage generator 220 can step down the Vdd supply voltage to a lower supply voltage. For example, the linear regulator can step down an 80V Vdd supply voltage to a lower 12V voltage, at an output current supply of between 5-25 mA. The linear regulator in the voltage generator 220 can be embodied as an emitter-follower transistor linear regulator with Zener diode biasing, for example, although other types of active linear regulators, active DC-DC converters, and even passive voltage step-down or divider circuits can be relied upon.

The charge pump in the voltage generator 220 is configured to convert the output of the linear regulator to the Vshift voltage. The charge pump can convert a positive voltage to a negative voltage. The charge pump can be embodied as a switching regulator capable of providing an output Vshift voltage of between −5V to −15V, such as an output Vshift voltage of −5V, −6V, −7V, −8V, −9V, −10V, −11V, −12V, −13V, −14V, or −15V, based on an input voltage of 12V provided by the linear regulator in the voltage generator 220. The Vshift voltage output of the voltage generator 220 provides a potential for level shifting the Vctrl signal to the level-shifted Vctrl_S signal, as described in further detail below.

The voltage reference generator 222 is configured to generate a reference voltage Vref for the level shifter 224 based on the Vshift voltage provided from the voltage generator 220. The voltage reference generator 222 can output a scaled ratio of the Vshift voltage as the Vref voltage, as described in further detail below with reference to FIG. 4. The voltage reference generator 222 can be embodied as a resistor divider, a resistor divider network, a linear regulator, or another type of reference generator.

The level shifter 224 receives the Vctrl signal, the Vref voltage from the voltage reference generator 222, and the Vshift voltage from the voltage generator 220 as inputs. The level shifter 224 is configured to generate and provide the level-shifted Vctrl_S signal as an output. The level shifter 224 is configured to shift the voltage levels of the Vctrl signal to different, but corresponding, voltage levels of the level-shifted Vctrl_S signal. As an example, the level shifter 224 can be configured to expand the voltage range or levels of the Vctrl signal from between −2V and −5V to between −2V and −8V. The level shifter 224 is not limited to shifting the potentials of the Vctrl signal to any particular voltages for the Vctrl_S signal, however. Rather, the level shifter 224 can be designed to shift voltage levels of the Vctrl signal to a range of different voltage levels depending on the type and design of the amplifier 202.

As noted above, the levels of the Vctrl signal at the bias control input 16 may be insufficient as a gate bias to completely stop the flow of current through the amplifier 202 (i.e., to completely pinch-off the transistor in the amplifier 202). For example, the bias and sequence circuit 20 shown in FIG. 1 may generate a Vctrl signal having an insufficient negative potential to completely stop the flow of current through the amplifier 202. Thus, the level shift circuit 210 is designed to expand or shift the voltage levels of the Vctrl signal to the level-shifted Vctrl_S signal. The relatively greater potentials (e.g., larger negative voltages) of the Vctrl_S signal can be sufficient to turn off the depletion mode transistor or transistors in the amplifier 202. Overall, the level shift circuit 210 facilitates the replacement of the pallet amplifier 100 shown in FIG. 1 with the pallet amplifier 200 shown in FIG. 2, because it is not necessary to alter the Vctrl signal or the Vdd supply voltage when the pallet amplifier 200 includes the level shift circuit 210. That is, the pallet amplifier 200 can be operated by the Vctrl signal and Vdd supply voltage provided by the bias and sequence circuit 20 shown in FIG. 1, even if the bias and sequence circuit 20 was not designed for use with the amplifier 202. Thus, the pallet amplifier 200 can replace the pallet amplifier 100 in the amplifier system 10 without also replacing the bias and sequence circuit 20.

The level shift circuit 210 is also designed to “boot-up” to level-shifting operations during the sequencing of the Vctrl signal and the Vdd supply voltage from the bias and sequence circuit 20. The level shift circuit 210 is designed to pass the original levels of the Vctrl signal to the amplifier 202 (or pass the levels with a nominal potential drop), for the purpose of gate biasing the amplifier 202, even before the Vdd supply voltage is provided to the pallet amplifier 200. As noted above, the bias and sequence circuit 20 can be designed to provide a Vctrl bias voltage of −5V before providing or turning on a Vdd supply voltage of 80V. Because the Vshift, Vref, and other voltages in the level shift circuit 210 are derived from the Vdd supply voltage (which is supplied later in time), the level shift circuit 210 is designed to pass the Vctrl bias voltage of −5V to the amplifier 202 before the Vdd supply voltage is provided to the pallet amplifier 200.

FIG. 4 illustrates a detailed view of the level shift circuit 210 shown in FIG. 3 according to various aspects of the embodiments described herein. Particularly, FIG. 4 illustrates more detailed views of the voltage reference generator 222 and the level shifter 224 shown in FIG. 3. As noted above, the voltage generator 220 is configured to convert the relatively larger Vdd supply voltage to a relatively lower Vshift voltage. The voltage generator 220 can output a Vshift voltage of a negative potential based on a Vdd supply voltage of a positive potential. For example, the voltage generator 220 can output a Vshift voltage of between −6V and −8V based on a Vdd supply voltage of 80V. The voltage generator 220 can also output other Vshift voltages based on the Vdd supply voltage. The Vshift voltage is provided by the voltage generator 220 to the voltage reference generator 222 and to the level shifter 224.

In some cases, the Vctrl signal may supply sufficient current to generate the Vshift voltage at a suitable level of power. Thus, in another example, the voltage generator 220 can generate the Vshift voltage based on power supplied from the Vctrl signal. The voltage generator 220 can be simplified in that case, for example, and may include only the charge pump without the linear regulator.

The voltage reference generator 222 includes a voltage divider of resistors R1 and R2, as shown in FIG. 4. The voltage reference generator 222 provides the Vref reference voltage based on the Vshift voltage provided from the voltage generator 220. The value of Vref can be set or selected based on a ratio of R1 and R2, as would be understood in the field, and −4.2V is an example value of Vref. Vref can be set to other reference potentials in other cases.

The level shifter 224 includes a first amplifier A1, a second amplifier A2, resistors R3-R6, a capacitor C1, and diodes D1-D3, arranged and electrically connected as shown. The amplifiers A1 and A2 can be embodied as differential operational amplifiers. The amplifiers A1 and A2 can be embodied as rail-to-rail input/output amplifiers suitable for use as buffers or level shifters, current shunt monitors, active filters, comparators, and in other configurations.

The amplifier A1 is electrically connected in the level shifter 224 for operation as a buffer, and the amplifier A2 is electrically connected in the level shifter 224 to operate as a comparator. The amplifiers A1 and A2 are electrically connected to have stacked operating rails. That is, the upper rail (+) of the amplifier A1 is electrically coupled to ground potential. The lower rail (−) of the amplifier A1 is electrically coupled to the upper rail (+) of the amplifier A2. The lower rail (−) of the amplifier A2 is electrically coupled to the Vshift voltage from the voltage generator 220. The lower rail (−) of the amplifier A2 is also electrically coupled to the Vctrl signal through the diode D3.

The Vctrl signal is provided to the non-inverting input of the amplifier A1 through the resistor R3. The inverting input of the amplifier A1 is electrically coupled to the output of the amplifier A1, so that the amplifier A1 is configured as a buffer. In the configuration shown, the amplifier A1 provides an output voltage that closely tracks the levels of the Vctrl signal.

The Vctrl signal is also provided to the non-inverting input of the amplifier A2 through the resistor R6. The Vref reference voltage is provided to the inverting input of the amplifier A2 through the resistor R5. A filter network including the capacitor C1 and the resistor R4 is coupled between an output of the amplifier A2 and the inverting input of the amplifier A2. The amplifier A2 is configured to perform as a comparator.

In operation, the level shifter 224 is configured to shift one or more voltage levels of the Vctrl signal to one or more second voltage levels, to generate the level-shifted Vctrl_S signal. Stated differently, the level shifter 224 can expand one or more voltage levels of the Vctrl signal to generate the level-shifted Vctrl_S signal. The level-shifted Vctrl_S signal is generated by the level shifter 224 based on a comparison of the Vctrl signal to the Vref reference voltage. For example, when Vctrl is greater than Vref, then the amplifier A2 is off and presents a high impedance output. The amplifier A1 is on, and the voltage level of the Vctrl signal is passed through the amplifier A1, which acts as a buffer. The output of the amplifier A1 is followed through the diode D1 to provide the level-shifted Vctrl_S signal. When Vctrl is less than Vref, then the amplifier A2 is active and presents the negative rail voltage Vshift as an output. The Vshift voltage is followed through the diode D2 to provide the level-shifted Vctrl_S signal.

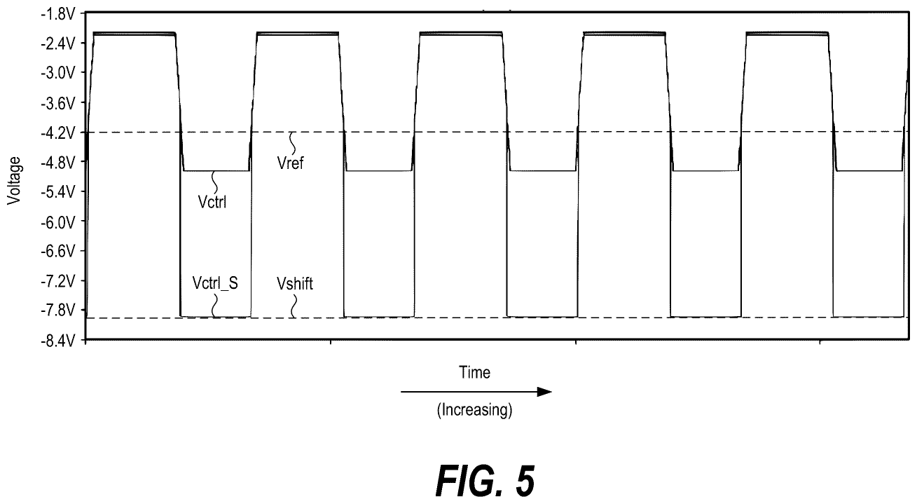

FIG. 5 illustrates example waveforms of the gate bias control signal Vctrl and the level-shifted gate bias control signal Vctrl_S over time. FIG. 5 also illustrates an example Vref voltage and an example Vshift voltage. Vctrl, Vref, and Vshift are provided as inputs to the level shifter 224, as shown in FIG. 4, and Vctrl_S is provided as an output of the level shifter 224. Thus, FIG. 5 illustrates the input and output voltages and voltage waveforms of the level shifter 224. The voltage changes of the Vctrl and Vctrl_S signals are depicted representative examples in FIG. 5. The embodiments described herein are not limited to use with any particular voltages or voltage ranges, and the Vctrl and Vctrl_S signals can be generated to or at other voltage levels.

As shown in FIG. 5, the level shifter 224 is configured to shift one or more voltage levels of the Vctrl signal to one or more second voltage levels for the level-shifted Vctrl_S signal. The bias and sequence circuit 20 (see FIG. 1) can generate and provide the Vctrl signal, as described above. When the voltage of Vctrl is greater than Vref (e.g., Vctrl=−2.2V and Vref=−4.2V) as in the example depicted, then the level shifter 224 outputs the voltage of (or substantially the voltage of) the Vctrl signal as the level-shifted Vctrl_S signal. Referring to FIG. 4, when the voltage of Vctrl is greater than Vref, then the amplifier A2 is off and presents a high impedance output. At the same time, the amplifier A1 is on when the voltage of Vctrl is greater than Vref, and the voltage level of the Vctrl signal is passed through the amplifier A1. The output of the amplifier A1 is followed through the diode D1 to provide the voltage of Vctrl as the level-shifted Vctrl_S signal.

Referring again to FIG. 5, when Vctrl is less than Vref (e.g., Vctrl=−5V and Vref=−4.2V), then the level shifter 224 outputs the voltage of (or substantially the voltage of) Vshift as the level-shifted Vctrl_S signal. Referring to FIG. 4, when Vctrl is less than Vref, then the amplifier A2 is active and presents the negative rail voltage Vshift as an output. The Vshift voltage is followed through the diode D2 to provide the level-shifted Vctrl_S signal. Overall, the level shift circuit 210 expands the voltage range or levels of Vctrl from between about −2V and −5V to a range of between about −2V and −8V for Vctrl_S. The level shift circuit 210 is not limited to level shifting of certain voltages or voltage ranges, however. Rather, the level shift circuit 210 can be designed to shift voltage levels of the Vctrl signal to a range of different voltage levels depending on the design of the amplifier 202 and the needs of the design.

The level shift circuit 210 is also designed to “boot-up” to the level-shifting operations shown in FIG. 5. As noted above, the bias and sequence circuit 20 can be designed to provide a Vctrl bias voltage of −5V, for example, before providing or turning on a Vdd supply voltage of 80V. Because the Vshift, Vref, and other voltages shown in FIG. 5 are derived from the Vdd supply voltage, the level shift circuit 210 is also designed to simply pass the Vctrl bias voltage from the bias and sequence circuit 20 to the amplifier 202, without level shifting, during the period of time before the Vdd supply voltage is provided to the pallet amplifier 200.

Thus, the waveforms shown in FIG. 5 are representative of those expected when the bias and sequence circuit 20 is providing the Vdd supply voltage, because the Vshift and Vref voltages are generated from the Vdd supply voltage. Before the Vdd supply voltage is provided, the level shift circuit 210 is designed to pass the original potentials of the Vctrl signal as the level-shifted Vctrl_S signal. Thus, before the Vdd supply voltage is supplied, the level shift circuit 210 is configured to provide the Vctrl_S signal having the same or substantially the same potentials as the Vctrl signal. The Vctrl_S signal would overlap more closely with the Vctrl signal shown in FIG. 5 in that case.

The power amplifiers and semiconductor power transistors described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaln)-based Nitrides), GaAs, InP, InGaP, AlGaAs, etc. devices. However, the concepts of gate bias level shifting, as described herein, are not limited to use with any particular type of transistors or transistors formed from any particular type of semiconductor materials.

The concepts described herein can be applied to GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

The transistors described herein can be formed as field effect transistors (FETs), although the concepts can be applied to other types of transistors. Among other types of FET transistors, the transistors described herein can be formed as HEMTs, pseudomorphic high-electron mobility transistors (pHEMTs), metamorphic high-electron mobility transistors (mHEMTs), among other types of transistors. The FETs can include metal oxide or insulator semiconductors (MOSFET or MISFET) transistors and metal-semiconductor field-effect transistor (MESFETs). The transistors can include one or more field plates, such as source-connected field plates, gate-connected field plates, or both source-connected and gate-connected field plates.

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within +20% of a target value for some features, within +10% of a target value for some features, within +5% of a target value for some features, and within +2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A power amplifier, comprising:
a depletion mode power transistor; and
a level shift circuit configured to generate a level-shifted gate bias control signal for the depletion mode power transistor based on a gate bias control signal.

2. The power amplifier according to claim 1, wherein the level shift circuit comprises:
a voltage generator;
a voltage reference generator; and
a level shifter.

3. The power amplifier according to claim 2, wherein the voltage generator comprises a linear regulator and a charge pump.

4. The power amplifier according to claim 2, wherein the voltage reference generator comprises a resistor voltage divider.

5. The power amplifier according to claim 2, wherein:
the voltage generator is configured to generate a shifted voltage based on a supply voltage; and
the voltage reference generator is configured to provide a reference voltage based on the shifted voltage.

6. The power amplifier according to claim 1, wherein the level shift circuit is configured to shift a first voltage level of the gate bias control signal to a second voltage level for the level-shifted gate bias control signal based on a comparison of the gate bias control signal to a reference voltage.

7. The power amplifier according to claim 1, wherein the level shift circuit comprises:
a voltage generator configured to generate a shifted voltage based on a supply voltage;
a voltage reference generator configured to generate a reference voltage based on the shift voltage; and
a level shift circuit configured to shift a first voltage level of the gate bias control signal to a second voltage level for the level-shifted gate bias control signal based on a comparison of the gate bias control signal to a reference voltage.

8. The power amplifier according to claim 1, wherein the level shift circuit is configured to expand first voltage levels of the gate bias control signal to second voltage levels for the level-shifted gate bias control signal.

9. The power amplifier according to claim 1, wherein the level shift circuit is configured to expand first voltage levels of the gate bias control signal to second voltage levels for the level-shifted gate bias control signal based on the gate bias control signal.

10. A level shift circuit for gate bias control, comprising:
a voltage generator configured to generate a reference voltage based on a supply voltage; and
a level shifter configured to receive a gate bias control signal for a power transistor and to generate a level-shifted gate bias control signal for the power transistor based on the reference voltage.

11. The level shift circuit according to claim 10, wherein the voltage generator comprises a linear regulator and a charge pump.

12. The level shift circuit according to claim 10, further comprising:
a voltage reference generator, wherein:
the voltage generator is configured to generate a shifted voltage based on the supply voltage; and
the voltage reference generator is configured to generate the reference voltage based on the shifted voltage.

13. The level shift circuit according to claim 10, wherein the level shifter is configured to shift a first voltage level of the gate bias control signal to a second voltage level for the level-shifted gate bias control signal based on a comparison of the gate bias control signal to the reference voltage.

14. The level shift circuit according to claim 10, wherein the level shift circuit is configured to expand first voltage levels of the gate bias control signal to second voltage levels for the level-shifted gate bias control signal.

15. The level shift circuit according to claim 10, wherein:
when the supply voltage is provided, the level shift circuit is configured to expand first voltage levels of the gate bias control signal to second voltage levels for the level-shifted gate bias control signal based on a comparison of the gate bias control signal to the reference voltage; and
when the supply voltage is not provided, the level shift circuit is configured to pass gate bias control signal as the level-shifted gate bias control signal.

16. A level shift circuit for gate bias control, comprising:
a voltage generator configured to generate a shifted voltage based on a supply voltage;
a voltage reference generator configured to generate a reference voltage based on the shift voltage; and
a level shifter configured to receive a gate bias control signal and to generate a level-shifted gate bias control signal.

17. The level shift circuit according to claim 16, wherein the voltage generator comprises a linear regulator and a charge pump.

18. The level shift circuit according to claim 17, wherein:
the linear regular is configured to step down the supply voltage to a lower supply voltage;
the charge pump is configured to convert the lower supply voltage to the shifted voltage; and
the lower supply voltage is a positive voltage and the shifted voltage is a negative voltage.

19. The level shift circuit according to claim 16, wherein the level shifter is configured to shift a first voltage level of the gate bias control signal to a second voltage level for the level-shifted gate bias control signal based on a comparison of the gate bias control signal to the reference voltage.

20. The level shift circuit according to claim 16, wherein:
when the supply voltage is provided, the level shift circuit is configured to expand first voltage levels of the gate bias control signal to second voltage levels for the level-shifted gate bias control signal based on a comparison of the gate bias control signal to the reference voltage; and
when the supply voltage is not provided, the level shift circuit is configured to pass gate bias control signal as the level-shifted gate bias control signal.
